(19) United States
(12) Patent Application Publication
(10) Pub. No.: US 2026/0166844 A1
(43) Pub. Date: Jun. 18, 2026

(54) HERMETICALLY CONNECTED ASSEMBLY

(71) Applicant: SCHOTT AG, Mainz (DE)

(72) Inventors: Jens Ulrich THOMAS, Mainz (DE); Antti MÄÄTTÄNEN, Tampere (FI); Bernd HOPPE, Ingelheim (DE); Robert HETTLER, Kumhausen (DE); Christian OTT, Ampfing (DE)

(73) Assignee: SCHOTT AG, Mainz (DE)

(21) Appl. No.: 18/707,826

(22) PCT Filed: Nov. 10, 2022
(86) PCT No.: PCT/EP2022/081460

§ 371 Date: May 6, 2024

(30) Foreign Application Priority Data
Nov. 11, 2021 (DE) 10 2021 129 411.8

(51) Int. Cl. B32B 7/05; B32B 15/08; B32B 17/06; C03C 27/02

(52) U.S. Cl. CPC B32B 7/05; B32B 15/08; B32B 17/061; C03C 27/02; B32B 2457/00

(57) ABSTRACT

The invention relates to a hermetically connected assembly having a first substrate which is transparent in some regions and/or partly transparent for at least one wavelength range, a metal foil having a contact surface which adjoins a contact surface of the first substrate, and a laser joint line or a plurality of binding points for directly and indirectly joining the metal foil with the first substrate at or in the contact surfaces. The laser joint line or the plurality of binding points reach into the first substrate and into the metal foil, and the two joint partners are directly melted together. In the process, the metal foil is configured to be flexible in order to compensate for an unevenness of the contact surface of the first substrate.

### FIELD OF THE INVENTION

The present invention relates to a hermetically bonded assembly, to a housing, to a method of producing a hermetic bond and to the hermetically bonded assembly produced by the method.

### BACKGROUND AND GENERAL DESCRIPTION OF THE INVENTION

It is fundamentally known that two or more parts can be combined to form a hermetically sealed bond or a housing by means of different laser methods. For example, hermetically bonded glass-glass junctions are known from the applicant's European patent specification EP 3 012 059 B1. This discloses a method of producing a transparent part for protection of an optical component. A novel laser method is presented here.

Bonds in which different materials are bonded to one another are under constant development. Among these, the metal-glass junction is of particular interest since specifically the combination of metal and glass has a multitude of possible uses. Thus, improvements and new applications are specifically achievable in the field of biophysics or technical medicine, especially with regard to bioprocessors and applications in aviation.

When a hermetically sealed housing is being constructed, it is possible therein to protect one component or components within the housing from adverse environmental conditions. For instance, it is possible for sensitive electronics, circuits or sensors, for example, to be disposed in a hermetically sealed housing, in order, for example, to construct and insert medical implants, for example in the cardiac region, in the retina or generally for bioprocessors. Fields of application may also be for MEMS (microelectromechanical systems), in sensor technology, as for a barometer, a blood gas sensor or a glucose sensor etc., or else for electronic applications, to provide an antenna, to provide conductor tracks on glass components etc. The present invention is additionally able to provide a “CTE bridge” by mounting and firmly anchoring a material having a distinctly different CTE (coefficient of thermal expansion) on a substrate. Especially in the field of wristwatch production or generally in the field of wearables and devices that are to have a waterproof or pressure-resistant construction, there may likewise be potential applications. In particular, it is possible to improve a cover for a smartwatch or the like with the present invention. Various fields of use for the present invention can also be found in aerospace, in high-temperature applications, in the electromobility field, for example for production of fuel cells, in analytics, for example in the form of optical inputs and flow cells, and also in the field of microoptics.

By contrast with a bond of two identical components to one another, the problem arises in the case of use of different materials that the two joining partners often have poor adhesion to one another, if they can be made to form a bond at all. The present invention builds on the preliminary studies that were conducted in-house by the applicant. In this context, reference is made to unpublished German patent application DE 10 2020 129 380.1, which is hereby incorporated by reference in its entirety.

It was an object of the present invention to provide a hermetically bonded assembly between two components made of different material, namely the bond of a first substrate, for example a glass material or vitreous material, to metal. A further object was that of providing housings as well, wherein two parts made of different material are to be bonded to one another.

In particular, one aspect of the present object was that of being able to produce the hermetically bonded assembly or the housing in a sufficiently durable manner, in order particularly to ensure that the two parts do not become apart from one another or even become detached from one another under a gentle force. One aim of the present invention is thus to provide more reliable and longer-lived hermetically bonded assemblies or housings.

A hermetically bonded assembly according to the invention comprises a first substrate which is transparent at least in regions and/or at least to some degree to at least one wavelength range. The first substrate is disposed with a contact face adjacent to a contact face of a metal foil. In other words, a metal foil is disposed atop the first substrate; for example, the metal foil adheres to the first substrate or has been pressed onto it or temporarily bonded to it.

The substrate and metal foil are typically first arranged one on top of another for bonding thereof, i.e. stacked one on top of another for example. Gravity can then press the upper substrate onto the metal foil beneath. Orientation above or beneath is merely descriptive, since the arrangement may of course assume any orientation in space, and even juxtaposition does not depart from the scope of protection. The metal foil is typically disposed with a longer side of its extent adjoining the substrate. For example, substrate and/or metal foil are in the form of slices or in two-dimensional form and therefore each have at least one larger flat side. However, it is typically impossible or undesirable to apply a force for “pressing together” of substrate and metal foil, since this can result in permanent “baking” of various stresses (e.g. shear stresses) into the substrate in the joining process. The hermetic bond or housing will then possibly have lower strength or a higher tendency to fracture when the joining process is performed under stress. It may therefore be impossible for the substrate to be arranged sufficiently tightly to a metal component for the laser joining process to lead to a good-quality and reproducible result. In order to further improve the joining outcome, therefore, the metal foil is included. Under the inventive use of the metal foil, it is thus possible to increase the final strength of the housing or substrate, and for metal foil and substrate to be joined to one another in a stress-free manner. Freedom from stress differentiates this method in particular from “hot” coating processes, such as the sputtering application of a metal coating. When such processes are employed, stresses can remain in the coated substrates after cooling. Moreover, the use of a metal foil may be less costly in terms of production, in particular less costly than the sputtering application of a metal coating to the substrate, the metal foil can be provided in a thicker and more robust form than such a coating, and, moreover, the metal foil can balance out or bridge over unevenness in the surface of the substrate in a simple manner. It is thus possible to completely dispense with an intermediate step for sputtering on the substrate, which further shortens process run times and lowers costs.

The hermetically bonded assembly further comprises at least one laser join line or a multitude of bond points for direct and immediate joining of the metal foil to the first substrate, at or in the contact areas. The laser join line or the multitude of bond points firstly reaches into the first substrate and secondly into the metal foil, and joins the first substrate to the metal foil by direct melting. In other words, first substrate and metal foil have been joined to one another in the laser join line.

“Contact face” in the context of this application is a region or part of a surface, or else a whole side of the respective substrate or metal foil, with which the respective substrate comes to rest or is disposed adjacent to another substrate or the metal foil. The substrate is typically disposed beside or atop the metal foil. When substrate and metal foil are in direct and immediate contact, a touch contact surface is formed. The touch contact surface is thus, for example, part of an area of the contact face where the distance between the two substrates is sufficiently small that it is no longer optically measurable.

The first substrate is as planar as possible at the contact faces. However, an absolutely planar surface is achievable here only theoretically, since, depending on the viewing scale, even in the case of polished surfaces, it is still possible to find depressions, elevations or curves, or a multitude of the aforementioned variations. Complete touch contact is therefore difficult to achieve, particularly when a substrate such as a glass or the like is to be disposed on a metal component. Instead, substrates, even if only to a very small degree, are dished, inclined, curved or provided with depressions or elevations. For example, a touch contact face can be defined when the first substrate has an average distance from the metal foil of not more than 1 μm, preferably not more than 0.5 μm and further preferably not more than 0.2 μm.

Yet a further reduction in the variations of the substrate surface may possibly be very complex. In some substrates, a sufficiently great reduction in variation may not even be possible or desirable. For instance, the polishing of the surface may in turn alter optical properties of the first substrate, or possibly alter surface tensions of the first substrate. A substrate in the case of further reduction may also begin to form a dish shape or become deformed in some other way, as a result of which the resulting distance from the desired joining partner—i.e. the air gap established—further increases in size. It is also possible under some circumstances for a polished surface, especially of a metal object for a laser joining process, to be disadvantageous since an increased amount of reflection or scatter occurs at a polished surface and, accordingly, the exact positioning and power deposition for the joining operation is made more difficult, or the joining operation possibly cannot be conducted in such a way.

In the context of the invention, it has been found that, surprisingly, it is possible to use a metal foil in order to bring about particularly good adhesion between the metal foil or a metal object and the first substrate. The characteristics of the metal foil are such that it is flexible and can adapt to the contact face of the first substrate. In particular, the metal foil may compensate for its own unevenness, i.e. unevenness in the surface of the metal foil. Because this unevenness (usually curves) can be balanced out, the distance between metal foil and first substrate can be reduced. For example, it is possible to use an aluminum foil pressed onto one side of the first substrate. The aluminum foil persists here in a shape that it receives as a result of pressing onto or adapting to the first substrate. In other words, the metal foil is deformed, for example curved, kinked or dished, and adapts to the contact face, as a result of which it takes on a shape complementary to the contact face. The metal foil thus becomes a complementary metal foil since it increases the contact area of the first substrate such that the touch contact face between metal foil and first substrate is increased and/or air gaps are reduced.

In particular, the deformation of the metal foil for adaptation to the contact face is nonelastic, such that the metal foil retains the altered shape even without significant application of force. This may be important, for example, in the case of a glass substrate or vitreous substrate since, under some circumstances, stress fields would be introduced into the substrate if the joining operation took place under external application of force. The joining operation when the metal foil is used may thus more preferably take place without external application of force, since the metal foil persists in the altered shape and does not return to the original shape of its own accord. The altered shape is accordingly intrinsically stable and irreversible, and the deformation is in particular nonelastic. For example, the first substrate's own weight, when it is applied to the metal foil, is sufficient for the metal foil to adapt to the first substrate, and an improved contact face can be provided without occurrence of significant substrate stresses in the first substrate that could otherwise possibly be “baked” into the substrate by the joining operation.

The metal foil is preferably arranged along an outer edge region of the first substrate. In other words, the metal foil extends along the edge region, for example in the form of an internally open square or rectangle. For example, the metal foil covers the contact face of the first substrate in portions or in regions, i.e. in particular not completely. The metal foil can also be used to form one or more contact points on the contact face of the first substrate. The purpose of the metal foil may be the establishment of an improved bond of the first substrate to a metal component, wherein the metal foil is first welded to the first substrate by means of the laser joining method presented here, and the metal component can then be bonded to the first substrate by means of the metal foil bonded thereto by conventional joining methods.

Additionally or alternatively, the metal foil may have a vertical section. By means of the vertical section, it is possible to introduce a molten bond in the laser join line not just in the horizontal plane but also, in sections, in a vertical region. In addition, the component to be joined, especially a metal component, may provide a frame or envelope of the hermetic assembly in that, additionally or alternatively, a lateral join by means of a conventional joining method has been moved into the lateral side region.

The metal foil may additionally have vertical structures that can be introduced, for example, by punching with a profile, or by embossing. These vertical structures may serve as an aligning aid or centering aid in the aligning of the component to be joined to the substrate.

Rather than a metal component, it is also possible, for example, to join a plastic component or a crystal component to the first substrate by the metal foil. Examples of crystal components are especially silicon wafers or germanium wafers, sapphire, yttrium oxide (Y2O3), zirconium oxide (ZrO2), aluminum oxide (Al2O3), yttrium-doped zirconium dioxide, yttrium-doped aluminum oxide, lanthanum-doped yttrium oxide, aluminum-doped aluminum nitride and magnesium-doped aluminum oxide.

The metal foil may have no flexibility (any longer) in the joining region, i.e. the region comprising the laser join line or the multitude of laser join lines, after introduction of the laser join line(s) because of the adhesion to the first substrate as a result of the joining process. Since the foil is inextricably bonded to the first substrate in the joining region, the metal foil in this region can remain flexible only when the first substrate is also flexible. However, the metal foil can remain flexible outside the joining region comprising the laser join line(s) even after introduction of the laser join line(s).

In the laser join line or a multitude of bond points, there is a mixing zone in which first substrate material and metal foil material are mixed. In the mixing zone, metal material of the metal foil may have entered the first substrate. In the mixing zone, it is also possible for first substrate material to have entered the metal foil. More preferably, in the mixing zone, both metal material of the first substrate has entered the metal foil and material of the metal foil has entered the first substrate. The mixing zone may have a thickness measured in a direction at right angles to the contact faces, where the thickness of the mixing zone may have a thickness of preferably at least 1 μm, further preferably 2 μm or more, further preferably 5 μm or more.

The metal foil is sufficiently flexible that it can adapt to the contact face. This is dependent on the material among other factors. In order still to be sufficiently flexible, the metal foil may have a thickness of 500 μm or less, preferably 250 μm or less, further preferably 100 μm or less, further preferably 50 μm or less. On the other hand, it is advantageous when the metal foil has a minimum thickness at which the metal foil can still be reliably welded to the first substrate. The minimum thickness of the metal foil may be 10 μm or more, preferably 20 μm or more, further preferably 40 μm or more.

The underside of the metal foil on the opposite side from the contact face may be designed such that it is capable of providing advantageous surface properties for the subsequent conventional welding process. For some methods, the underside takes the form of a surface with very low roughness. However, other methods may be favored by a higher roughness in the μm range, or require a groove and furrow structure.

On the underside, on the opposite side from the contact face, the metal foil may have a weld rib. This weld rib may form in the joining operation. For example, a nose or weld rib may form on the underside when the metal foil is subject to significant point heating in the laser welding operation and metal foil material escapes from the joining zone. The weld rib may be advantageous since this can simplify the later conventional welding to the metal component when a weld rib on the underside is present here. Such a metal component may then be inextricably bonded, i.e. joined, to the metal foil welded to the first substrate.

The metal component is preferably cohesively bonded to the metal foil by conventional joining methods, i.e. with application of heat and/or pressure, with or without welding fillers, especially by metal fusion welding such as arc welding. The use of such a welding method for the bonding of a metal component—for example a watch housing for a smartwatch—to the assembly—for example a watch glass or watch cover—is actually enabled in this way by the inventive use of the metal foil, since metal can be joined here to metal.

It is thus possible, for example, to deliver the hermetic assembly to which the metal foil has already been joined for further processing, such that the watch manufacturer may not even need to provide additional installations in order to conduct the laser joining method; instead, if the hermetic assembly is delivered in finished form, the watch manufacturer (or the manufacturer of the final housing, for example of the watch) will be able to use conventional joining methods to produce a hermetic and permanent bond, which may mean a distinct simplification of the production process on the part of the manufacturer of the final housing—for example the watch manufacturer.

The mixing zone preferably extends 1 μm or more into the first substrate. The mixing zone preferably extends 5 μm into the first substrate. Further preferably, the mixing zone extends into the first substrate to the same extent as the resolidified zone, such that the mixing zone covers the resolidified zone. For example, the mixing zone extends into the first substrate to roughly the same extent as it does into the metal foil. This is surprising at first glance since, for example, in the case of a metal-glass composite, the CTE of the metal foil is 3 to 10 times higher than the CTE of a glass (first substrate). The heat capacity and thermal conductivity of the metal is also typically considerably higher than that of the first substrate. However, it has been found that it is advantageous to establish the mixing zone in the laser join line or the bond points such that this extends into the metal foil roughly to the same extent as into the first substrate, and hence to improve the joined bond.

The mixing zone has a width, where the width of the mixing zone is preferably greater than the height of the mixing zone in the first substrate. The width of the mixing zone may also be 50% or more greater than the height of the mixing zone, further preferably 100% or more greater than the height of the mixing zone.

The width may, for example, be measured at the contact face between the first and first substrate, and be measured in a direction parallel to the contact face and at right angles to the laser join line.

The at least one laser join line or the multitude of bond points may also comprise a resolidified zone, where the resolidified zone has a height measured in the direction at right angles to the contact faces. The height of the resolidified zone may preferably be not more than 20 μm, preferably not more than 10 μm and further preferably not more than 5 μm.

The resolidified zone may also extend not more than 20 μm into a depth of the first substrate, preferably not more than 10 μm and even further preferably not more than 5 μm.

The resolidified zone of the at least one laser join line or a multitude of bond points may extend along the laser join line or be disposed in the respective bond points. The resolidified zone, at the contact face between the first substrate and the metal foil and in a direction parallel to the contact face, may have a width of 10 μm, for example +/−5 μm. This width may preferably be 20 μm+/−10 μm, further preferably 30 μm+/−10 μm.

The resolidified zone may also have a width in a direction parallel to the contact face and at right angles to the laser join line which is greater than the height of the resolidified zone.

The resolidified zone is particularly advantageously as small as possible, meaning that the parameters for the irradiation with the joining laser may be selected such that the resolidified zone is as small as possible. The resolidified zone has essentially no benefit to the joining operation since no material is mixed there so as to give rise to interdigitation or adhesion between the first substrate and the metal foil. The resolidified zone thus absorbs laser energy without improving the aim of adhesion. Moreover, cracks and/or holes or cavities will possibly arise in the resolidified zone in the course of cooling, which can possibly be explained in that the joined material expands on heating, hence generating stresses, and contracts again on cooling.

The mixing zone may thus preferably be made as large as possible, whereas the resolidified zone should be made as small as possible. The mixing zone preferably has a height of at least ⅕ of the height of the resolidified zone, further preferably ½ of the height of the resolidified height; further preferably, the mixing zone has the same height as the resolidified zone. For example, given a height of the mixing zone of 5 μm, the height of the resolidified zone above the mixing zone is 25 μm when the height of the mixing zone is ⅕ of the height of the resolidified zone. When the height of the mixing zone is 10 μm and, above that, the height of the resolidified zone of the first substrate is likewise 10 μm, the height of the resolidified zone will then correspond to the height of the mixing zone. The mixing zone may also have a greater thickness than the resolidified zone, for example 1.5 times the thickness or more, for example 5 times the thickness of the resolidified zone.

The metal foil may also have a resolidified zone beneath the mixing zone. It can be left aside whether the size of the resolidified zone of the metal foil would be disadvantageous for the joining operation, as is the case for the first substrate. On the contrary, the material of the first substrate can penetrate into the resolidified zone of the metal foil and cause dendrite formation there, i.e. effect anchor-like bonding of the first substrate to the metal foil via one or more dendrites, where the dendrites can extend up to the resolidified zone of the metal foil.

In the mixing zone, first substrate material and metal foil material may be arranged so as to cause cohesive interdigitation between the first substrate material and the metal foil material. The hermetically bonded assembly may also comprise a mutually fused interdigitation structure between the first substrate and the metal foil. In the mutually fused interdigitation structure, there may be material that protrudes or is recessed or undercut, such that this can strengthen the adhesive bond of the hermetically bonded assembly. Such a mutually fused interdigitation structure provides a cohesive bond, which is advantageous especially when the cohesive bond between different materials, as the case may be, is capable of providing only a low bond strength or a low cohesive bond strength. The interdigitation structure works here like a microscopic zip fastener.

In the mixing zone, there may be metal material from the metal foil in the form of droplets and/or dendrites, where the arrangement as droplets and/or dendrites brings about strengthening of the bond.

It is even more remarkable that, even in at least one of the resolidification zones, metal material from the metal foil and/or first substrate material may have penetrated, especially in form of droplets, molten material and/or dendrites, and brings about strengthening of the bond. In other words, the joining partners, i.e. the first substrate material and/or the metal foil material, may be selected and/or the beam generators may be adjusted and/or set up to adjust the joining process such that metal material from the first substrate and/or metal foil material penetrates into the resolidification zone assigned to the respective other component.

For example, first substrate material, as a result of or after introduction of the laser join line, may have an amorphous region or zone. Such an amorphous region, i.e. amorphous metal material for example, can further improve interdigitation.

The contact face of the first substrate has at least one touch contact region in which the first substrate is in two-dimensional touch contact with the metal foil. The touch contact area may especially have an average separation of not more than 1 μm, preferably not more than 0.5 μm and further preferably not more than 0.2 μm. It is possibly the case that, for technical reasons or other reasons, for example, very small gas inclusions or contaminants, such as dust particles or unevenness from a polishing operation, will be unavoidable in the contact plane. This may also result from possible unevenness even into the microscale region in the contact plane or at the surfaces of the components. The touch contact face may correspond to the contact face when contact can be established over the full area.

The laser join line may bond the first substrate to the metal foil in such a way that these can be separated only with overcoming of the holding force. The joining may also be achieved to such a significant extent that separation can be achieved only with destruction of the first substrate when the shear strength is greater than the material strengths, for example the edge strength, of the first substrate. For example, the shear strength can be ascertained with employment of standard ISO 13445:2003. The shear strength of the bond between the metal foil and the first substrate may, for example, be greater than 10 N/mm², preferably greater than 25 N/mm², further preferably greater than 50 N/mm², even further preferably greater than 75 N/mm² and finally, most preferably, greater than 100 N/mm².

It is preferable when the contact side of the first substrate is flat, i.e. planar in particular. The contact side of the first substrate may be polished when the metal foil adapts to the contact site. The contact side of the first substrate may, for example, have an average roughness Ra of not more than 0.5 μm, preferably not more than 0.2 μm, further preferably not more than 0.1 μm, even further preferably not more than 50 nm and, finally, preferably not more than 20 nm. The metal foil adapts to the contact side of the first substrate and may follow the unevenness of the contact side. If the metal foil itself is not provided in planar form, for example since it deforms as a result of warpage (i.e. bending), for example rolls up, the adaptation of the metal foil may relate to the adaptation of the metal foil to the planar contact side of the first substrate.

The laser join line is introduced by means of a joining laser. For example, the joining laser has a wavelength in the range from 1000 nm to 1100 nm, preferably 1030 nm to 1060 nm, when it is an infrared laser, or else a wavelength of 500 to 550 nm. It is possible to use, for example, an ultrashort pulse laser with pulse lengths in the region of 50 ps or less, preferably 10 ps, further preferably 1 ps or further preferably 500 fs or less.

The joining laser has a beam focus. The beam focus may have a beam waist 2w0. In addition, the joining laser has a beam width 2Wₗₐₛₑᵣ for the joining process that may be not less than the beam waist 2w0. The focal plane for the introduction of the laser join line may be shifted distally relative to the joining plane. The beam width 2Wₗₐₛₑᵣ is greater than the beam waist 2w0 especially when the focal plane for the penetration of the laser join line has been shifted distally. In particular, the focal plane lies in the metal foil on introduction of the laser join line. The focal plane has preferably been shifted distally into the metal foil by 10 μm+/−10 μm, further preferably 20 μm+/−10 μm.

The beam width 2Wₗₐₛₑᵣ at the joining plane is preferably 4 μm+1 μm, further preferably 4 μm+2 μm, further preferably 4 μm+3 μm. This can be achieved, for example, when the focal plane lies in the metal foil on introduction of the laser join line, i.e., for example, has been shifted distally into the metal foil by 10 μm+/−10 μm or 20 μm+/−10 μm. Alternatively or cumulatively, the laser beam can be widened or narrowed in front of the writing objective, for example by means of a stop or a telescope, in order to adjust the beam width 2Wₗₐₛₑᵣ to the desired width.

The metal foil preferably consists entirely of metal material or a semimetal material. The metal foil preferably comprises metal or a semimetal as defined by the Periodic Table. The metal foil may comprise or consist of at least one of aluminum, molybdenum, tungsten, silicon, platinum, silver and gold. The metal foil may also comprise an alloy. In particular, the metal foil may comprise or consist of at least one of carbon, copper, manganese, chromium, magnesium, cobalt, nickel, tin, zinc, niobium, palladium, rhenium, indium, tantalum, titanium or iridium.

The first substrate is preferably a transparent substrate. The first substrate may comprise or consist of glass, glass-ceramic, silicon, germanium, sapphire or a combination of the aforementioned materials. One example of a glass having good transparency in the IR region is the calcium aluminate glass available under the IRG11A name from SCHOTT AG.

The first substrate may also be or comprise a fiber sheet or a fiber rod. Such fiber sheets or fiber rods comprise a multitude of optical fibers, where each of the fibers has an elongated glass core. The cores are surrounded by a glass sheath, such that the sheath together with the cores forms a rigid, continuous glass element. The cores have a higher refractive index than the sheath, such that the light can be directed past the glass cores by total reflection. Alternatively, the light can also be guided by Anderson localization, as, for example, in the waveguide known from DE 10 2020 116 444. In this case, glass cylinders of high and low refractive index and with varying diameters are in a nonuniform chaotic arrangement or arranged nonuniformly according to an unambiguously predetermined rule. The glass element of the multifiber optical fiber has two abutting faces, where the cores end in the two end faces, such that the light can be guided along the cores from one end face to the other.

The first substrate may also comprise or consist of ceramic material, especially oxide-ceramic material. The first substrate may also comprise or consist of a crystalline material or a crystal, especially crystalline quartz, yttrium oxide (Y2O3), zirconium oxide (ZrO2), aluminum oxide (Al2O3), yttrium-doped zirconium dioxide, yttrium-doped aluminum oxide, lanthanum-doped yttrium oxide, aluminum-doped aluminum nitride and manganese-doped aluminum oxide. The dopants are preferably each metal oxides.

The first substrate may comprise or consist of quartz glass, borosilicate glass, aluminum silicate glass, a glass-ceramic, such as Zerodur, Ceran or Robax, an optoceramic, such as aluminum oxide, spinel, pyrochlore or aluminum oxynitride, potassium fluoride crystal or chalcogenide glass.

In one development, the hermetically bonded assembly can have a spacer for fixing a distance between the first substrate and the metal component. The spacer may be inserted or embraced horizontally between the metal foil, i.e. in regions that have been left open by the metal foil, for example in a window framed by the metal foil. For example, the first substrate may then be in contact with the metal component via the spacer. In other words, the spacer may be arranged, for example, in regions on the contact face of the first substrate, such that the substrate comes into contact or touch contact with the spacer, but a distance remains between the contact face of the first substrate and the contact face of the metal component outside the spacer, for example in the size of the thickness of the spacer and/or in the thickness of the metal foil.

The spacer may fill the region between substrate and the component to be joined to the substrate, especially the metal component. For instance, the substrate may abut the metal component in the joined state. For example, the spacer may take the form of a coating or likewise take the form of a metal foil on the first substrate. The spacer may also be in one-piece form with the first substrate, for example in the form of a bulge that forms an offset or an elevation there. For example, the spacer may be produced on polishing of the contact face of the first substrate, when regions of the contact face of the first substrate are not polished and hence elevations remain there. Specifically in the case of sapphire as the first substrate, as in particular as watch glass, where there is typically already complex polishing of the sapphire glass, there may be an additional or altered polishing operation on the sapphire glass in the polishing step, such that no additional working step is required in the production.

The spacer may be applied by sputtering. The spacer may comprise a directly deposited Lithoglass layer. The spacer may also be printed on, for example by the inkjet printing method. The spacer may also be the result of 3D printing. The spacer may extend along the laser join line, in which case the spacer is disposed outside the laser join line or outside the regions of the bond points. The spacer may abut the first substrate, for example the metal component. However, the spacer is preferably intended for inextricable bonding of the first substrate to the metal component. The spacer may have a thickness of at least 5 μm, further preferably a thickness of at least 10 μm and even further preferably a thickness of at least 20 μm. The spacer preferably has the same thickness as the metal foil.

The spacer may additionally have structures in the form of elevations, bulges and/or depressions, which can serve as an aligning aid or a centering aid and can facilitate the exact positioning of the substrate in relation to the component to be bonded to the substrate.

In one development of the invention, it is also possible to provide at least one escape zone to accommodate molten material from the laser join line or the bond point. The at least one escape zone is preferably disposed adjacent to the laser join line or to the multitude of bond points. In other words, the escape zone is arranged such that molten material, especially at the moment of creation of the laser join line, can escape into the escape zone. For example, the escape zone may be arranged around and hence in communication with the laser join line, such that material which is heated in molten form in the laser join line can escape slightly into the escape zone. The molten material can follow a pressure gradient here in the process of escaping.

For example, on introduction of the laser join line, the first substrate and/or the metal foil can show expansion, for example thermal expansion. Since the laser heats material only locally, and so material remains in the solid state around the laser join line, it is possible that enormous stresses may arise between the material of the laser join line and the material surrounding the laser join line, which can cause cracks, such as stress cracks, or cavities. When the escape zone is kept clear, molten material can escape into the escape zone, such that the formation of cracks or cavities is reduced. The at least one escape zone, or else buffer zone or relaxation zone, is further preferably disposed between the first substrate and the metal foil, for example at the contact face there.

The escape zone may also be formed so as to include the spacer that allows the two contact faces to come to rest facing one another at a defined distance when the first substrate is disposed on the metal foil. The cavities that form in the regions where there is no spacer may be configured or arranged in advance such that these can be utilized as escape zone for material that escapes in the laser join operation. As a result, the resultant laser join line has lower stress and as a result may be stronger or provide a higher bond strength, and it is possible at the same time to keep stresses away from the first substrate, meaning that fewer stress cracks or cavities are formed in the first substrate.

If the zone in which molten material is mixed together is referred to as mixing zone, and the adjoining zones of the laser join line as resolidification zones, it is specifically the resolidification zones that are problematic in that cracks or cavities can form there as a result of the introduction of the laser join line. This is disadvantageous particularly when the first substrate, for example, is a single crystal such as a sapphire in which damage resulting from the introduction of a laser join line cannot be remedied by the subsequent introduction of an offset subsequent laser join line. With the present concepts, especially of the escape zone and/or the spacer, it is therefore possible to keep the resolidification zone as small as possible, but at the same time to allow the mixing zone to be as large as possible or to project as far as possible into the substrate or the metal foil. In the ideal case, the mixing zone is as large as the resolidification zone, which means that the mixing zone fully covers the resolidification zone, and no resolidification zone as such remains apparent. In that case, mutual adhesion is particularly good, but at the same time the formation of cracks or cavities is minimized.

A second laser join line can be achieved in that the same laser is adjusted again to a previous or similar joining position, i.e. the new laser focus overlaps with an already established or already employed focal point. The introduction of a second laser join line, especially into the still-warm or hot first laser join line, can also be accomplished by use of a double focus in the laser generator. For example, it is possible for this purpose to use a beam divider or a diffraction grating, or else two laser generators. The second laser join line is introduced here into joining partner material that is still warm, especially still molten.

Such an effect, i.e. the introduction of laser energy into still-warm or even still-molten material, can also be achieved, for example, when the laser generator has a burst function, and in this way a multitude of laser dots can be introduced into the arrangement in an overlapping manner and over a short period of time. In other words, adjacent to a focal point of the first laser join line, a further focal point is employed and a second laser join line is introduced after a defined time delay and/or at a defined spatial distance. A second laser join line can possibly further improve the bond and hence increase the bond strength of the metal foil on the first substrate.

In the context of the invention, a hermetically sealed housing is also shown, especially having a hermetically bonded assembly, as already described in detail above. The hermetically sealed housing comprises a first substrate which is transparent at least in regions and/or at least to some degree to at least one wavelength range and a metal foil, wherein the metal foil is arranged with a contact face adjacent to a contact face of the first substrate. The metal foil is made to be flexible in order to compensate for unevenness in the contact face of the first substrate. A function region is additionally provided. The function region may be disposed between the metal foil and the first substrate. The function region may be disposed at the contact face of the first substrate, for example framed by the metal foil.

The housing has at least one laser join line or a multitude of bond points for direct and immediate joining of the metal foil to the first substrate, at or in the contact areas, especially around the function region for hermetic sealing of the function region. The laser join line or the multitude of bond points reaches firstly into the first substrate and secondly into the metal foil and joins these directly to one another by fusion.

In the hermetically sealed housing, the laser bond line of the housing may be fully continuous around the function region. Additionally or alternatively, a potential air gap, i.e. a spacing between the first substrate and the metal foil, in the laser bond line may be universally less than 0.75 μm, preferably less than 0.5 μm and further preferably less than 0.2 μm.

The function region of the housing may have a hermetically sealed accommodation cavity for accommodation of an accommodation object, such as an electronic circuit, a sensor or MEMS. Secondly, the accommodation object(s) may optionally also be disposed in the region of the metal component. The function region may be an optical coating of the first substrate, a layer comprising one or more light-emitting diodes (LEDs), a polarizer.

Also within the scope of the invention is a method of producing a hermetically sealed bond from at least two parts, comprising the steps of: providing a first substrate and a metal foil, pressing the metal foil onto the first substrate such that, at a contact face which is formed between the metal foil and the first substrate, the metal foil is in touch contact with the first substrate, wherein the metal foil adapts to unevenness in the contact face of the first substrate via the pressing and is shaped permanently. This is followed by hermetically tight bonding of the metal foil and the first substrate to one another by direct joining to one another in the region of the at least one contact face, such that a mixing zone is formed, which firstly projects into the first substrate and secondly into the metal foil and joins these directly to one another by fusion.

A contact face may be regarded as a plane formed by the mutually inclined faces of the two components to be brought into contact. The touch contact face means part of the contact face where the distance between the two substrates is so small that it is no longer measurable optically. Finally, in the context of the present invention, a good face is defined as that where the distance between the substrates is sufficiently small, as will be described in detail hereinafter, or there is in fact actual contact between the two substrates. In general, the contact face is larger than or the same size as the good face, and the good face is in turn larger than or the same size as the touch contact face. Both the first substrate and the metal foil may each have at least one contact face. The contact plane may be regarded as the plane in which contact takes place between first substrate and metal foil. If the metal foil is permanently deformed or has adapted to the contact face of the first substrate, the contact plane is correspondingly also “deformed”, i.e. follows the contact structure of the aligned contact faces.

In other words, the metal foil is first arranged beneath or on the first substrate, i.e., for example, introduced into a stack, where gravity presses the upper, typically first substrate onto the metal foil. Orientation above or beneath is meant merely in a descriptive manner since, of course, the components can assume any orientation in space, and even juxtaposition is not intended to leave the scope of protection. The two components are typically arranged alongside one another by the longer sides of their extent.

In particular, no other materials or layers are present or inserted between the first substrate and the metal foil, for example adhesives or glass frit or the like. It is possible that very minor gas inclusions or contaminants, such as dust particles, are unavoidable for technical reasons. This may also be the result of any unevenness even in the microscale region between the substrate layers or at the surfaces of the substrate layers. When the joining zone or laser bond line generated by the laser, in a preferred manner, for example, provides a height HL between 4-25 μm, it is possible by means of the laser bond line to ensure a hermetic seal since the distance between the two substrates that possibly arises can be bridged.

One or the laser bond line may enclose the function region circumferentially at a distance DF. The distance DF circumferentially around the function region may be constant, such that the laser bond line is disposed at about the same distance on all sides around the function region.

The distance DF may also vary depending on the application, which may possibly be more favorable for production-related reasons, for example when a multitude of housings is being joined in a common step, or when the function region has a round or arbitrary shape and the laser bond line is being drawn in a straight line. Even if the cavity has optical properties, for example takes the form of a lens, such as a convergent lens, the laser bond line may be formed around the cavity and may possibly have different distances from the cavity. A housing may also comprise multiple cavities.

The method may further comprise the step of: checking the hermetic bond of the at least two substrates by ascertaining a distance profile between the at least two substrates. The following step may also be included: ascertaining a first bond quality index Q1 for checking of the mechanical strength or hermeticity of the bond.

The first bond quality index Q1 can be ascertained as Q1=1−(A−G)/A. A here represents the area of the contact area, and G a good area. The good area G corresponds in particular to the touch contact area; the good area G may describe part of the contact area where the distance between the components of the first substrate and metal foil is less than 5 μm, preferably less than 1 μm and further preferably less than 0.5 μm, most preferably, finally, less than 0.2 μm. The bond quality index Q1 may be not less than 0.8, preferably not less than 0.9 and further preferably not less than 0.95.

The contact area may have a useful region N, and the useful region may be used to calculate the first bond quality index Q1. In that case, Q1 is ascertained as Q1=1−(N−G)/N.

In the context of the method, it is possible for this purpose to detect backscatter that results from the irradiation of the arrangement with incident radiation on at least one contact face of the arrangement. In other words, the arrangement is irradiated or illuminated such that backscatter is generated from the incident radiation at the surfaces. This backscatter may be the reflected incident radiation which is reflected to a certain degree at one of the surfaces. In the case of two substrates, i.e. where a further substrate is disposed opposite the metal foil, there may be three possible surfaces for this purpose where such reflection may already occur. These are the top face of the first substrate, the inside of the second substrate and the outside of the second substrate.

In other words, the first substrate has an outer face or else outer flat face which is aligned to the environment and is essentially two-dimensional or flat. Adjoining the outer flat face and typically oriented at a right angle to the outer flat face, for example with a circumferential configuration around the edge of the outer flat face, is a circumferential narrow face. In one example, the first substrate can be described as a sheet or cuboid having two faces of large area (i.e. the outside and the inside) and four smaller faces disposed between the large-area faces, which are especially at right angles to the two large-area faces and adjoin the large-area faces. In that case, the four smaller faces collectively form the circumferential narrow face, and the top face forms the outer flat face of the first substrate. The top face typically has a larger surface area than the smaller faces of the circumferential narrow face together. These remarks relating to sizes and size ratios may analogously also be applicable to further substrates.

In a region in which the substrate is in touch contact with the metal foil, there is insignificant reflection, if any, on the insides, and so this proportion is comparatively small. If there is a separation there, i.e. the substrate in this subregion is not in touch contact with the metal foil, incident radiation is reflected in a certain proportion at all three surfaces. In the case of more substrates, for example three substrates, there may correspondingly be more surfaces to consider.

The backscatter from the substrate stack which is collected by a measurement or observation device is used to ascertain a first bond quality index Q₁ of the contact face of the arrangement. For example, the first bond quality index Q1 is ascertained before the first substrate is joined to the metal foil. The method may also include the step of: ascertaining a second bond quality index Q2 of the contact face of the hermetically tightly sealed bond, where, in particular, Q2 is greater than Q1. Moreover, in particular, Q2/Q1 is greater than 1.001.

The backscatter preferably generates a pattern, especially an interference pattern; further preferably, this pattern is generated from the superimposition of the incident radiation with the backscatter at the at least one contact face of the housing. In that case, it is possible to configure the measurement or observation device such that it recognizes/detects this interference pattern and uses it to calculate or derive the distance between substrate and metal foil.

The pattern from the backscatter may have an arrangement where the pattern extends around one or more defect sites. In other words, the pattern may be arranged particularly around those sites where the substrate is not in touch contact with the metal foil. In that case, it is particularly simple to use the measurement or observation device to locate the sites where the substrate is not in touch contact with the metal foil. A defect site may be characterized in that the separation at these defect sites is greater than 5 μm, preferably greater than 2 μm and further preferably greater than 1 μm, greater than 0.5 μm, or else preferably greater than 0.2 μm. In other words, a defect site is more preferably present exactly where the criteria for a good area G are not met. In that case, the contact face between the substrate and the metal foil may be fully divided into good area G and defect site F.

The corresponding assignment of regions may, in one example, be identifiable by an interference pattern in the form of Newton's rings. When the incident radiation is set within the visible light range, for example with λ=500 nm, each Newton ring shows a difference in height of λ/2=250 nm. When, for example, the occurrence of three Newton rings exists as limiting criterion for the finding of whether a good region is present, it is possible in an optical image analysis of a backscatter from the housing to define that region as good region where the distance between substrate and metal foil is less than or equal to 3*λ/2=750 nm.

The scope of the invention also includes the housing produced by the method presented above.

The proposed housing is especially suitable for use as watch housing. Further fields of use relate in particular to devices for optical analysis, for example endoscopy, optical inputs to sample vessels or reactor vessels, and flow cells.

The invention is elucidated in detail hereinafter by working examples and with reference to the figures, where identical and similar elements are in some cases given the same reference numerals and the features of the different working examples may be combined with one another.

### BRIEF DESCRIPTION OF THE FIGURES

The figures show:

FIG. 1 a first embodiment of a hermetic bond,

FIG. 1a a detail from a joining zone prior to laser joining,

FIG. 1b detail of a joining zone with introduced laser join line,

FIG. 2 top view of a hermetic bond, shown here as housing with function region,

FIG. 3 lateral section view of an embodiment of a hermetic bond,

FIG. 4 lateral section view of a hermetic bond with metal component to be attached,

FIG. 5 lateral section view of a hermetic bond with attached metal component,

FIG. 6 perspective view of a hermetic bond with window,

FIG. 7 lateral section view of a hermetic bond with only partial coverage with metal foil,

FIG. 8a embodiment of a housing,

FIG. 8b further embodiment of a housing with lateral frame,

FIG. 9a-9h embodiment for production steps of a hermetic bond or of a housing,

FIG. 10 further embodiment of a hermetic bond with edge joining,

FIG. 11 the embodiment of FIG. 10 with attached metal component,

FIG. 11a further embodiment of FIG. 10 with laterally attached metal component,

FIG. 12 further embodiment of a hermetic bond,

FIG. 13 a fiber rod welded into a flange,

FIG. 14 a hermetic housing with a crystal component and

FIG. 15 the production of multiple hermetic housings on a wafer.

### DETAILED DESCRIPTION OF THE INVENTION

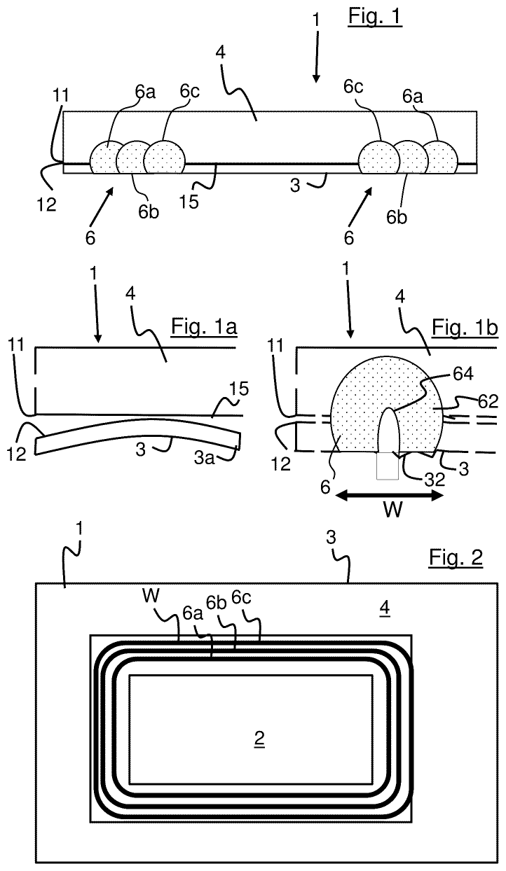

With reference to FIG. 1, a first embodiment of an inventive hermetic bond 1 is described, with dielectric 4 or first substrate 4 disposed on a full-area metal foil 3. The dielectric 4 or first substrate 4 has been placed onto the metal foil 3 such that its inside 11 comes to rest on the inside 12 of the metal foil 3. The two joining partners 3, 4 are therefore in contact with one another. Depending on the specific surface characteristics, the joining partners 3, 4 may be in two-dimensional touch contact with one another. If the surface of the first substrate 4 is rough, the joining partners 3, 4 may also at first be in touch contact only partially or in regions. If the joining partners 3, 4 are stacked one on top of another, merely by virtue of gravity, there will be a minimum degree of touch contact between the joining partners 3, 4. In this case, the metal foil 3 may be pressed onto the inside 11 of the first substrate 4 and become permanently deformed, such that it can compensate for any unevenness on the inside 11 of the first substrate 4.

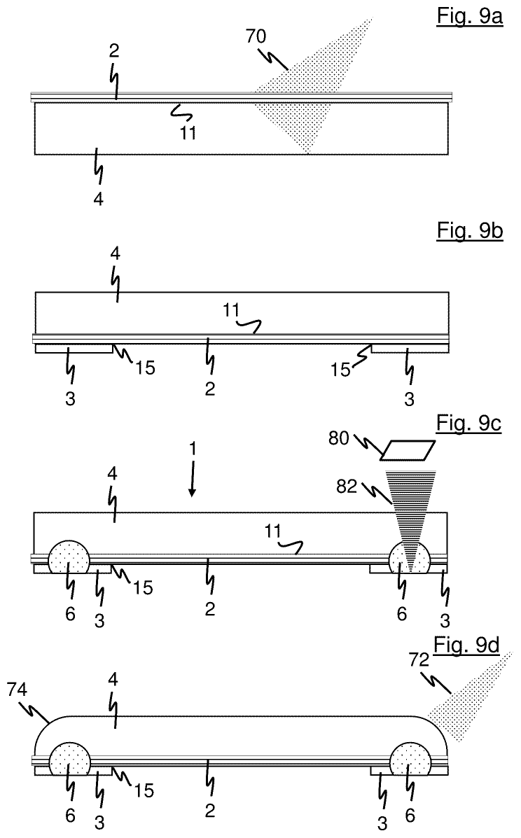

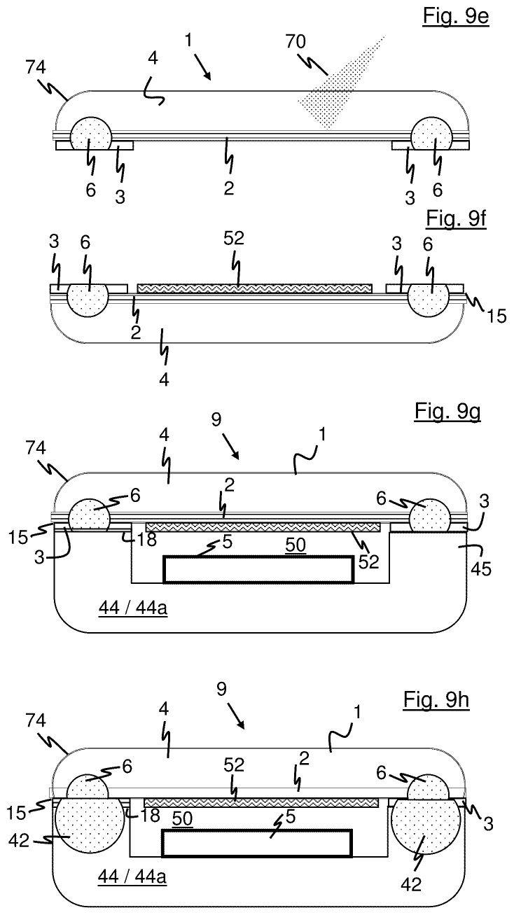

In the example of FIG. 1, three laser join lines 6a, 6b, 6c or bond points 6a, 6b, 6c have been introduced in order to join the two joining partners 3, 4 to one another. The joining points/lines 6a, 6b, 6c are placed along the sides of the joining partners 3, 4, with a laser 80 (cf., for example, FIG. 9c) being used to target the joining points from above (based on the drawing). The focal plane is preferably set beneath the region of the inner faces 11, 12. The focal plane is preferably adjusted such that it comes to rest in the metal foil 3, for example offset by 10 to 20 μm into the metal foil 3, i.e. 10 to 20 μm below the inner face 12 of the metal foil 3. This can have the effect that the laser beam 82 at the contact plane 15 achieves a desired width of preferably 4 μm+/−1 μm, further preferably 4 μm+/−2 μm, further preferably 4 μm+/−3 μm. This width can also be achieved via appropriate beamforming in front of the objective.

If, in the case as shown in FIG. 1, the two joining partners 3, 4 come to rest with their insides 11, 12 immediately adjacent to one another, i.e. are in particular in two-dimensional touch contact, the contact plane 15 is also shown in the same way by the two insides 11, 12 as in FIG. 1.

FIG. 1 also shows three laser join lines 6a, 6b, 6c that cross one another, such that the laser join lines 6a, 6b, 6c also interact with one another. It is possible here to prompt or achieve various effects depending on the objective. For example, the laser join lines need not be set under warm-in-warm conditions; instead, the successive laser join line 6b is only inscribed when the previous laser join line 6a has already cooled. The process of cooling of the laser join line proceeds extremely quickly since only an extremely small total amount of thermal energy is introduced, and the metal material of the metal foil 3 predominantly has excellent thermal conductivity. With the first laser join line 6a, material of the two joining partners 3, 4 is already mixed together, and possible unevenness and separations (air gaps) are bridged with fusion to a small extent. Depending on the surface quality, for example in the case of large air gaps of up to 5 μm in the region of the contact area 15 to be joined, the joining by the first laser join line 6 a may possibly only be inadequate. But since the region of the contact area 15 to be joined is closed by the introduction of the first laser join line 6a, the air gaps, if present, are closed and the material is already at least “partly mixed”, optimal further mixing of the two materials of the joining partners 3, 4 can then be brought about by the introduction of a second laser join line 6b and optionally a third laser join line 6c.

FIG. 1a shows a detail of a joining zone prior to laser joining. The metal foil 3 is adapted to the unevenness in the first contact face 11, such that the metal foil 3 may possibly be no longer in the original smooth form but in a curved or complex surface form. The contact face 12 of the metal foil 3 may follow the shape defined by the contact face 11. This can ensure that a maximum distance of the contact plane 15 between first substrate 4 and metal foil 3 is not exceeded, and the metal foil 3 instead follows the contours of the first contact face 11.

FIG. 1b shows the detail of FIG. 1a with inserted laser join line 6. Since the distance between the two contact faces 11, 12 can be kept small in that the metal foil 3 seamlessly follows the irregularities in the contact face 11 of the first substrate and adapts to the contact face 11, it can be ensured that a laser join line 6 can also be introduced at the planned site of the joining step. This is because, if the distance between the two contact faces 11, 12 becomes too great, it may be the case that reliable joining and hence bridging of an air gap is impossible or constitutes only an inadequate bond. Through use of the metal foil 3, the distance between the joining partners 3, 4 remains small, and the introduction of the join line 6 is assured. The join line 6 includes the melt zone 62 in which material of the first substrate 4 and of the metal foil 3 is melted and mixed together. One (or more) bubble(s) 64 may occur within the join line 6, which points in the direction in which the laser 80 shoots, which is typically from above (based on the plane of the drawing, but typically also on the actual procedure). A bulge 32 or a recess may remain on the underside, which may possibly be advantageous for the later standard welding methods with a metal component, and acts like a weld rib.

FIG. 2 shows a top view of a hermetic bond 1, wherein the laser join lines 6a, 6b, 6c run circumferentially around a function region 2. In the figures that follow, for the sake of simplicity, only one laser join line 6 is shown, but it is also possible to use more laser join lines 6, 6a, 6b, 6c in each embodiment. In the embodiment of FIG. 2, the laser join lines 6a, 6b, 6c are run completely around the function region 2 in order thus to hermetically seal the function region 2 all round. In principle, a hermetic seal of the function region 2 may also be achieved even with a single laser join line 6. Shear strength is increased when two or more laser join lines 6, 6a, 6b, 6c are used; moreover, redundancy in the case of use of two or more laser join lines 6, 6a, 6b, 6c can possibly ensure or improve hermeticity.

For example, for testing or determining of the hermetic properties of the housing or hermetic bond 1, a gas leak test may be employed, for example with helium as leak gas. Hermetic integrity can be obtained especially when, at a pressure difference of 1 bar, the gas leakage rate between the interior and the environment of the hermetic bond is 1 10⁻⁷ mbar×Is⁻¹ or less, preferably 10⁻⁸ mbar×Is⁻¹ or less, further preferably 1 10⁻⁹×Is⁻¹ or less.

The molten zone 62 around the laser join lines 6a, 6b, 6c has the width W. An accommodation object 5 such as electronic circuits may be disposed, for example, in the function region 2 (cf., for example, FIG. 9g).

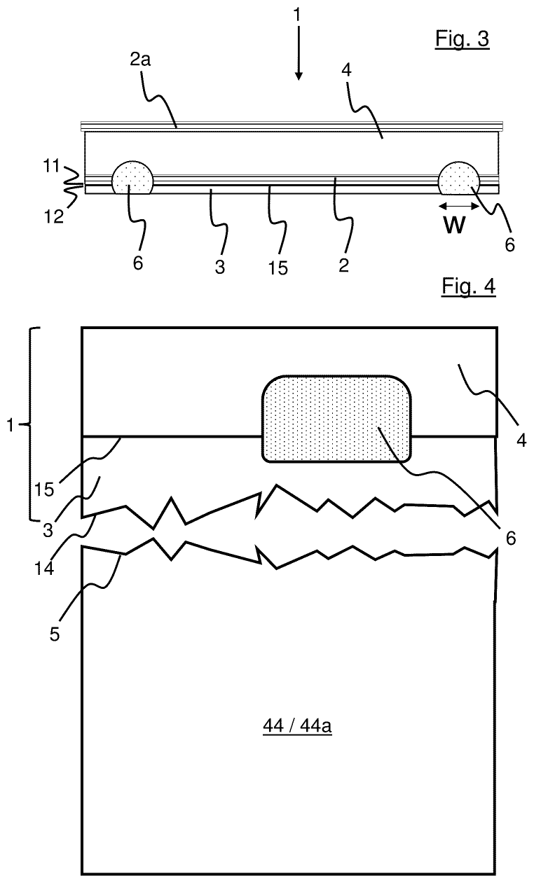

FIG. 3 shows a further embodiment of a hermetic bond 1 with a first substrate 4 which is typically transparent in the region of the laser wavelength used. The substrate 4 has, on its outside, a function region 2a, for example an optical coating, such as antireflection coating, a layer comprising lighting elements, especially comprising light-emitting diodes, a polarizer, or else a layer having electrical or electronic functions.

A function layer 2 is placed on the inside 11 of the first substrate 4. The function regions or function layers 2, 2a may have been applied to the first substrate, like a coating, or may have been disposed or bonded thereon. It may be advantageous when the function layer or function region 2 can be hit by the laser join line 6. In that case, the function region may have been applied over the full area, for example, on the inside 11 of the first substrate 4, and the laser joining method can nevertheless be conducted. This is the case in the embodiment of FIG. 3, and a full-area function layer 2 is shown, with a laser join line run along the outside of the substrate 4 and forming a continuous line (cf. FIG. 2). In order to show less complex representations, the resolution chosen has not been too high. In this regard, in all embodiments, reference is made implicitly to FIGS. 1a and 1b, which show corresponding details and hence also introduce significant advantages of the use of metal foil, namely in that the metal foil is capable of following all unevenness on the inside 11 of the first substrate 4.

With reference to FIG. 4, a hermetic bond 1 is shown, where the underside 14 of the metal foil, by way of illustration, has a distinctly uneven or rough form. The metal component 44 may also have a rough form since no smooth or polished surface is required there. This constitutes a considerable advantage with respect to earlier attempts, where the intention was to establish direct contact between metal component 44 and substrate 4. By means of the use of the metal foil 3 effectively as a mediator between metal component 44 and substrate 4, it is possible to considerably reduce complexity in the production and at the same time to achieve strong and durable and/or hermetic bonds.

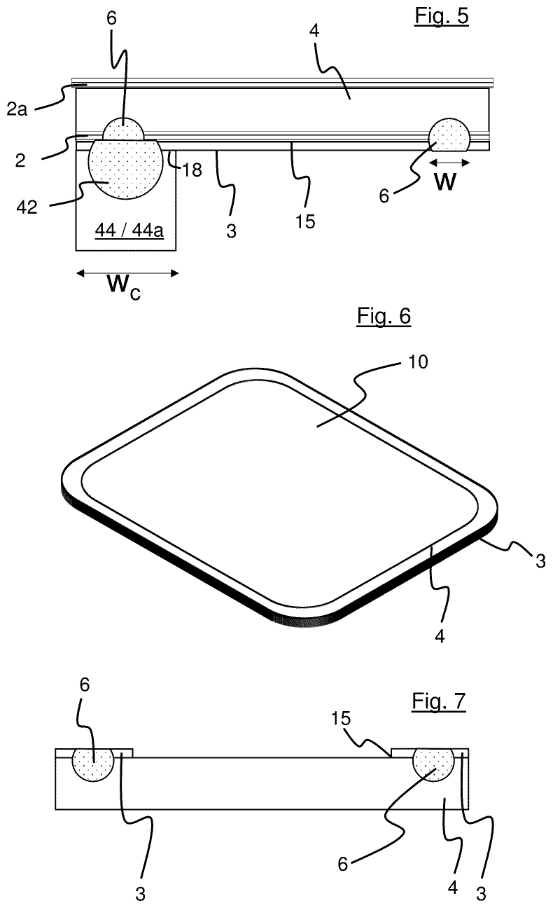

FIG. 5 shows the embodiment of FIG. 3 where a metal component 44 has been attached by conventional methods, i.e. by introduction of a join seam 42. Because the metal foil 3 contains metal, it is thus possible to use a conventional joining method, such as welding in particular, since metal is being bonded here to metal. It is especially advantageous here that the demands of the conventional joining methods on, for example, surface quality or surface characteristics are lower than for laser joining. It may therefore not be necessary to prepare, i.e. to polish, the underside of the metal foil 3 remote from the substrate and/or the contact face 18 of the metal body 44. The intermediate step of placing on the metal foil 3 may thus crucially simplify all the further method steps since, even in the case of rough or non-smooth insides 18 of a metal component 44 or plastic component 44a, a wide variety of different parameters may be set, namely in that the metal foil 3 firstly helps to bridge critical air gaps in the contact plane 15 and, thereafter, it is possible to use conventional joining methods such as metal welding in particular in order to bond the metal component ultimately by its contact face 18 to the metal foil 3, where it is possible to bridge considerably larger air gaps and nevertheless to establish a stable and reliable bond. It is thus immaterial that the metal foil 3 may itself have unevenness on its outside, for example transmits the unevenness that it receives on its inside 12, since the conventional metal welding method is more tolerant or robust to roughness or unevenness.

With reference to FIG. 6, an embodiment of a hermetic bond 1 is shown, wherein the metal foil 3 is arranged in a ring section around the outside of the substrate 4, and a window remains in the middle region of the substrate 4 in which there is no metal foil 3. In other words, the metal foil 3 is disposed merely in regions on the substrate 4.

FIG. 7 shows a cross section through such an embodiment with the metal foil 3 disposed only in regions and joined to the substrate 4 by means of the laser join line 6. In accordance with an arrangement of the metal foil 3 in regions, it is also possible to provide an arrangement of metal foil in sections, for example in order to provide electrical contact points on the substrate 4. Such a contact in sections by application of a metal foil 3 may have, for example, at least the size of a laser join point. The width W_{c} of the metal foil 3 may typically correspond to 1.5 times the width W of the laser join line 6 or more. In other words, the metal foil may have a comparatively small extent, e.g. 50 μm, 100 μm or more, 200 μm or more or a few hundreds of μm. The laser join lines 6, 6a, 6b, 6c are typically introduced in fully hermetic form in order to hermetically join the substrate 4 to the metal foil 3 and to establish an inextricable bond. The present invention, against the background of the known joining method already being practiced by the applicant, is also concerned with the consistent further development of various parameters or joining processes between joining participants 3, 4. In the context of the present invention, a focus here is on the bonding of the substrate 4 via the joining partner in the form of the metal foil 3 and a metal component 42 of any configuration. The substrate 4 is usually provided as a dielectric, especially as a glass, glass-ceramic, sapphire or the like. For example, the hermetic assembly 1 is provided in the form of a watchglass for a smartwatch. In this context, the very different CTE values of the different materials involved in the joining operation and, as the case may be, different brittleness and others will have to be taken into account. In particular, it has been found here that any remaining air gap between the substrate 4 and the first joining partner of the metal foil 3 may be critical, and this air gap may possibly have to be minimized over the entire region of the laser join line 6 to be introduced. Such an air gap that may be present and is possibly unwanted in the region of the laser join point of a laser join line 6 to be formed should advantageously be as small as possible, but at least small enough in order to be able to ignite a plasma at the laser join point by laser incidence. Plasma ignition is a prerequisite for applicability of a sufficient amount of heat at a point along the laser join line 6 by means of the laser 80. For this purpose, it is also advantageous when a resolidified zone can be restricted as far as possible to the region of the laser join line 6. In the context of this invention, it has been found that the advantageous use of the metal foil 3 allows the air gap to be reduced even further or continuously kept small enough over the course of the planned laser join line 6 in order to be able to help to reduce unfavorable optical impairments and/or cracks or pores that affect mechanical stability. As a result, it is possible to provide a further-improved product which is desired or required especially in very high-value products. Examples of these include the smartwatches already mentioned, but also, depending on the embodiment, applications in aerospace or medical technology. In that case, it is possible in the mixing zone 62 to mix material of the substrate 4 with material of the metal foil 3 if they are both put simultaneously into a molten state. For example, even the mixing in the mixing zone 64 can establish sufficient adhesion and hence a sufficient bond strength of the bond 1. For example, it may be desirable, by means of the permanent deformation of the metal foil 3 and the adaptation to the contact face 11 of the substrate 4, to leave an air gap in the contact plane 15 which is continuously not more than 0.5 μm in the region of the laser join line 6 to be introduced. For example, when the laser 82 is shot into the laser join line 6, dendrites and/or droplets may be formed in the region of material mixing, which provides or improves interdigitation between substrate 4 and metal foil 3. Droplets are thrown here into the respective other joining partner material; dendrites function as anchors or nails of the respective joining partner material into the respective other joining partner material.

Because the metal foil 3 is brought to an ideal distance from the contact face 11 of the substrate 4 in that the metal foil 3 adapts to the contact face 11, the air gap between the contact faces 11 and 12 can be brought to an ideal level. It is advantageous here when this ideal level is not zero, and instead a very small distance is retained, since it is possible thereby to create or maintain an escape zone into which material of the joining partners 3, 4 can escape when it is in molten form during the introduction of the laser join line 6. In this way, it is optionally possible to reduce cracks or cavities in the joining partners 3, 4. This may also be the case when the metal foil 3 is disposed only in regions or sections of the substrate 4, since air gap regions are automatically cleared here, into which molten material can flow during the joining operation. In this case, an air gap between the contact faces 11, 12 can be dispensed with completely, and complete touch contact can be established between metal foil 3 and substrate 4.

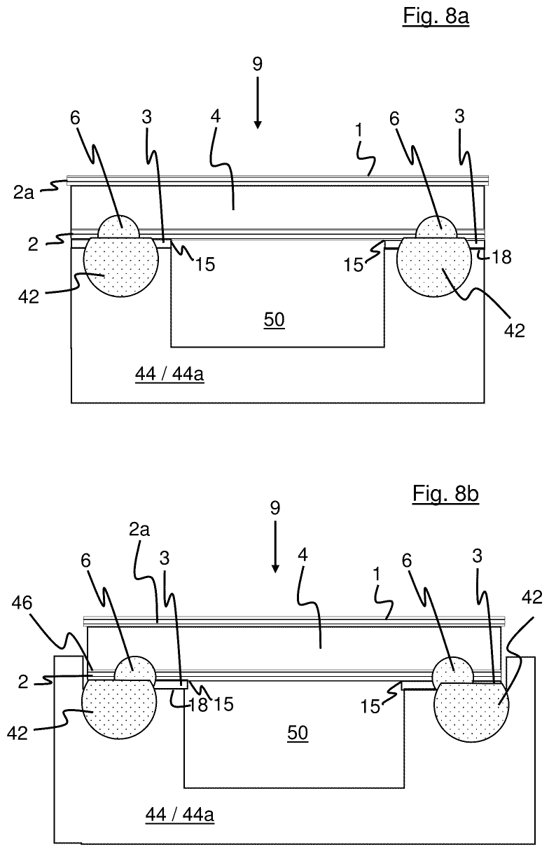

With reference to FIG. 8a, a hermetic housing 9 is illustrated, wherein a first substrate 4 has first been joined to a metal foil 3 by means of the laser join line 6. The function area 2 is disposed entirely beneath the substrate 4, where the laser join line 3 penetrates the function region 2. There is nevertheless a fully coherent portion of the functional region 2 within the inner region 50, which forms the top side of the cavity 50. For example, it is possible here to provide a layer 2 comprising LEDs, for example for formation of the display plane of a smartwatch. A weld seam 42 has been placed onto the metal foil 3 by conventional metal welding, by means of which the metal component 44 is attached and bonded firmly and hermetically to the assembly 1.

FIG. 8b shows a further embodiment of a housing 9, which hermetically seals a cavity 50. An assembly 1 includes the substrate 4 and the metal foil 3 that has been joined thereto by means of the laser join line 6. The metal foil 3 in turn is not inextricably bonded to the metal component 44 by the weld seam 42. The metal component 44 encompasses the assembly 1, such that the substrate 4 is retained in a protected and improved manner on its sides as well. The corner 46 of the substrate stack is thus also retained laterally by the metal component 44. The laser weld seam 6 and the weld seam 42 may fundamentally overlap here and also mix since metal material is present throughout the mixing zone 62, 64 (cf. FIG. 1b), and hence a metal weld can also take place there. Thus, directly and by means of the laser join line 6, the substrate 4 together with the metal component 44 is usable by a conventional joining method. In other words, a continuous molten bond is formed from the substrate 4 via the metal foil 3 into the metal component 44.

With reference to FIGS. 9a to 9h, the establishment of a hermetic bond 1 or of a housing 9 is described in individual steps. By a step shown in FIG. 9a, by means of spray application or sputtering, the function layer 2 is applied to the inside 11 on the substrate 4. The layer 2 may also be an optically active layer or a layer having electrical or electronic properties, for example light-emitting diodes (LED).

With FIG. 9b, the metal foil 3 is disposed in the region of the contact plane 15 on the inside 11 of the substrate 4. In this case, the metal foil 3 is disposed only in regions on the substrate 4, namely in an outer circumferential region. The step shown in FIG. 9c shows the introduction of the laser join line 6 for hermetic bonding of the metal foil 3 to the substrate 4 by means of the focused laser radiation 82 which is provided by the laser generator 80. For example, the hermetic assembly 1 is moved beneath the laser generator 80 on a movable stage with respect to the laser generator 80, and hence a laser weld seam is formed in the hermetic bond 1.

By the step shown in FIG. 9d, the finished laser join lines 6 have been created, with provision of aftertreated edges 74, for example by edge polishing or a machining step. It is optionally possible by the step shown in FIG. 9e to effect abrasive polishing 72 of the outside of the first substrate 4, or a further function layer 2a (FIG. 9e) may be applied on the outside of the substrate 4, for example a coating or optical finish.

With FIG. 9f, the hermetic assembly has been supplemented by a function layer 52, where the function layer 52 has LEDs for example.

With reference to FIG. 9g, the disposing of the hermetic assembly 1 on a metal component 44 is shown. An accommodation object 5 is disposed in the cavity 50 that forms. The accommodation object 5 may be a power source such as a battery or accumulator or a computation device or electronic components etc. The metal foil 3 is disposed adjacent to projections 45 of the metal component 44, such that the metal foil 3 is at least partly in touch contact with the projections 45. This ensures electrical conduction between the metal foil 3 and the metal component 44, which means that the prerequisite is satisfied in turn for the performance of a metal welding process.

With further reference to FIG. 9h, the introduced metal weld seam 42 is shown, by means of which the hermetic assembly 1 is inextricably bonded to the metal component 44. Overall, the cavity 50 is now hermetically cut off from the outside world and hence hermetically sealed.

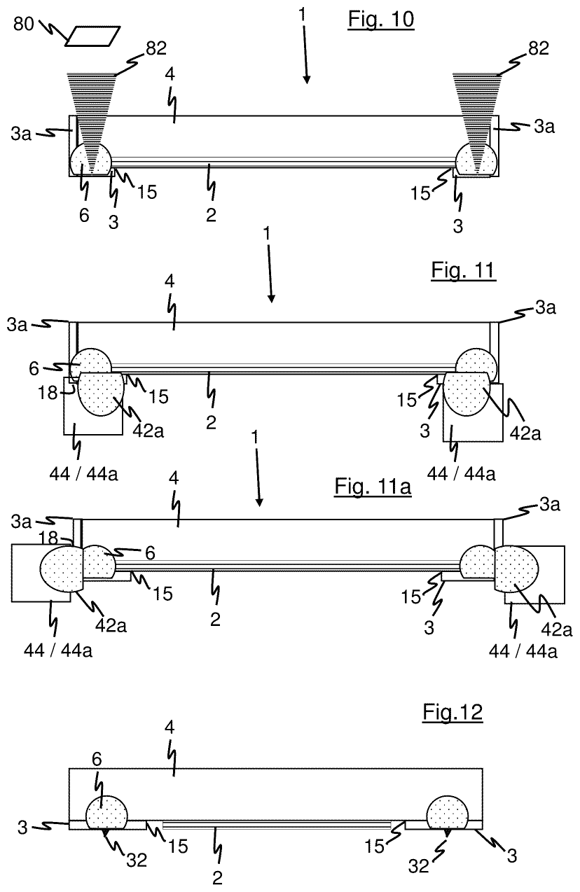

With reference to FIG. 10, an alternative arrangement of the metal foil 3 with a vertical section 3a is presented, wherein a molten bond in the laser join line 6 can be introduced not just in the horizontal plane but also in sections in the vertical region when the focused laser radiation 82 is introduced close enough in the edge region of the substrate 4. It is particularly advantageous here that, without the metal foil 3, 3a, it is typically not possible to work so close in the edge region of the substrate since not enough substrate material 4 remains to the side of the laser joining zone to be able to achieve a stress-free or reliable joining outcome. Instead, a laser would be deflected from the lateral edge of the substrate 4, and not enough energy would arrive at the focal point to be able to achieve a laser join 6. However, the shadowing or enclosure of the lateral edge of the substrate 4 with the metal foil 3, 3a allows the laser join seam 6 to be inscribed much closer to the edge of the substrate 4, and hence a larger area overall to remain between the laser join seams 6 for the target region and, at the same time, the possibly less attractive outer edge outside the laser weld seam 6 to be even smaller. Especially for smartwatches again, this configuration may be very attractive. It is optionally also possible to make a modified metal weld seam 42a even smaller and hence to even further reduce an unattractive edge region (cf. FIGS. 11 and 11a). The metal component 44 in this case can also provide a frame or envelope for the hermetic assembly 1 in that a lateral join can also be moved into the lateral edge region by means of the conventional joining method.

FIGS. 11 and 11a show corresponding possible arrangements or configurations that can also be combined with one another in order to establish the metal bond between metal foil 3, 3a and metal component 44 and hence to further improve the substrate-metal bond.

With reference to FIG. 12, finally, another embodiment of the hermetic assembly 1 is shown, wherein elevations or weld ribs 32 are shown beneath the laser join line 6, which can improve the electrically conductive bond to the metal component 44 to be mounted thereon, since these can establish reliable touch contact and hence a reliable electrically conductive connection, and simplify the subsequent metal joining step for introduction of the metal join line 42, 42a. It may be the case that the weld rib 32 can remain when the laser join line has been inserted, for example in that molten material forms the weld rib of its own accord, or else in that the metal foil 3, 3a has formed folds in the region of the laser join line that remain on the underside after the laser joining method. It is optionally already possible to prepare or make up the metal foil 3, 3a in order to provide weld ribs 32 from the outset on its underside, such that the later step of metal joining is simplified.

Rather than the metal component 44, it is also possible to attach a plastic component (44a), in which case conventional bonding methods between the metal foil 3, 3a and the plastic component may be used to form the housing 9.

It may also be the case that, rather than the metal component 44, a component made of fiber composite material is used, and this is bonded to the metal foil 3 in a conventional manner. Further possible materials for the component to be attached may include Teflon or PEEK.

The use of an intermediate foil, i.e. a metal foil, thus allows a cohesive bond to the component for a multitude of components such as, in particular, preferably the metal component 44 or else a plastic component 44a or a component made of fiber composite material.

Finally, it should additionally be added that, when only one laser join line 6, 6a, 6b, 6c or bond point is used, the width W of the laser join line corresponds roughly to the beam width 2wₗₐₛₑᵣ at the contact face 15 which is generated by the laser generator (cf. FIG. 10). Given N laser join lines 6, 6a, 6b, 6c in parallel arrangement, the width W of the laser join line achieved is typically less than or equal to N times the beam width 2wₗₐₛₑᵣ at the contact face 15, since the aim is, for example, an overlap with the region of laser action. Hₘ describes the height of the mixing zone 62, Hᵣ the height of the resolidified region. Ideally, Hₘ is greater than or equal to Hᵣ.

FIG. 13 shows a flange 102 set up, for example, for bonding to a reactor vessel. For the performance of optical studies on media accommodated in the reactor vessel, the intention is to enable optical input and to connect optical measuring instruments such as a spectrometer. For connection to a spectrometer or measurement head of a spectrometer, an adapter 104 is provided, which is connected to the flange 102, for example by welding. For an optical input, there is a hole 103 in the flange 102, into which a fiber rod 100 has been inserted. The fiber rod 100 serves as light guide in order to introduce light into the reactor vessel and to conduct light back out of the reactor vessel. For a hermetically tight connection between the light guide 100 and a flange 102, it is envisaged that the components are welded to one another.

As shown in the enlarged detail in FIG. 13, for this purpose, a metal foil 6 is placed on in the region of one end of the fiber rod 100 and bonded by laser point welding or a laser bond line 6 to the fiber rod 100 as the first substrate 4. The metal foil 3, as shown in FIG. 13, preferably has a vertical section 3a set up for a bond to the wall of the hole 103. Subsequently, the fiber rod 100 is inserted into the hole 103 and bonded via the metal foil 3 secured to the fiber rod 100 to the flange 102 that constitutes a metal component 44, for example by welding.

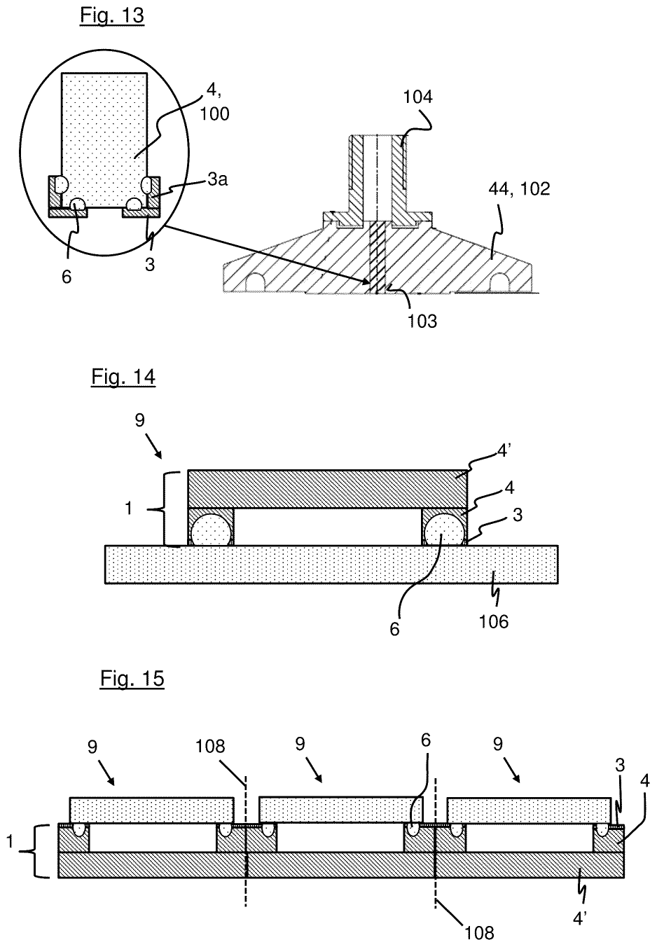

FIGS. 14 and 15 each show a hermetic housing 9 in which a substrate stack 1 is bonded to a crystal component 106. In the embodiment shown in FIGS. 14 and 15, the substrate stack 1 is formed from the first substrate 4 and a further substrate 4′. The further substrate 4′ forms a roof or floor of the housing 9. The first substrate 4 forms side walls of the housing 9. For joining of the first substrate 4 and the crystal component 106, as described above, a metal foil 3 is placed onto an end face of the first substrate 4 and bonded there, for example, via a laser bond line 6. Subsequently, the crystal component 106 can be placed onto the substrate stack 1 or, conversely, the substrate stack 1 can be placed onto the crystal component 106, and the housing 9 can be closed by means of a weld bond.

FIG. 15 shows how a multitude of housings 9, as already described with reference to FIG. 14, can be produced by processing whole wafers. For this purpose, the substrate stack 1 is formed by bonding a first substrate 4 in the form of a spacer wafer to the further substrate 4′. The spacer wafer comprises a recess or cavity for each housing 9 to be formed. Both the first substrate 4 and the spacer wafer may consist, for example, of a semimetal such as silicon or germanium or of a glass material, and be joined hermetically to one another via a laser bonding method directly, i.e. without a metal foil 3. Subsequently, a metal foil 3 with recesses for the individual openings that later form the interior of the housings 9 is placed onto the substrate stack 1 and bonded by means of a laser join line 6 or individual bond points. Subsequently, as shown in FIG. 15, individual platelets in the form of crystal components 106, for example, are placed on and welded to the metal foil 3. It is alternatively possible of course to place on and join a whole wafer as a crystal component 106. There follows singularization of the housings 9 formed by division of the substrate stack 1 along the dicing lines 108.

The present description has thus disclosed, in a complete and comprehensible manner, a method by which two different joining partners can be joined to one another by laser joining methods, namely in that a metal foil is used, which allows even better control over remaining air gap dimensions or further increases the touch contact area and hence increases the quality of the laser join line 6, 6a, 6b, 6c. The corresponding hermetically joined bond has also been described in detail and elucidated comprehensively. The present description thus includes a multitude of descriptions that may be perceived to be at odds with “conventional” knowledge or to be surprising. In this regard too, the present invention constitutes a further development of German patent application DE 10 2020 129 380.1 (which was still unpublished at the filing date of this application), to which reference is made here in full and which is incorporated into the present application in its entirety.

It will be clear to the person skilled in the art that the embodiments described above should merely be considered to be illustrative, and the invention is not restricted to these, but can be varied in various ways without leaving the scope of protection of the claims. Moreover, it is apparent that the features, regardless of whether they are disclosed in the description, the claims, the figures or in some other way, also define individual constituents of the invention, even if they are described collectively together with other features. In all figures, identical reference numerals refer to the same features, such that descriptions of features that may be mentioned only in one or at least not with regard to all figures may also be applied to these figures with regard to which the feature is not described in the description.

### LIST OF REFERENCE NUMERALS

1 composite or substrate stack
2, 2a function region
3 metal foil
3a permanent deformation of the metal foil
4 first substrate (e.g. dielectric, e.g. glass)
4′ further substrate
5 accommodation object
6, 6a, 6b, 6c joining zone or laser bond line
9 housing
10 window
11 contact face or inside of the first substrate
12 contact face or inside of the metal foil
14 underside of the metal foil
15 contact face between the joining partners
18 contact face of the metal component
32 elevation or weld rib
42 conventional join line or metal join line
44 metal component
44a plastic component
45 projection of the metal component
46 corner of the substrate stack
50 cavity or interior
52 function element, e.g. LED layer
62 melt zone or mixing zone
64 bubble
70 application means, e.g. sputtering nozzle
72 abrasive
74 aftertreated edge of the first substrate 4
80 laser generator
82 focused laser radiation
W width of the laser join line 6, 6a, 6b, 6c
100 fiber rod
102 flange
103 hole
104 adapter
106 crystal component
108 dicing line

1. A hermetically bonded assembly comprising:
a first substrate which is transparent in regions and/or to some degree to at least one wavelength range,
a metal foil,
wherein the metal foil is arranged with a contact face adjacent to a contact face of the first substrate,
a laser join line or a multitude of bond points for direct and immediate joining of the metal foil to the first substrate, at or in the contact areas,
wherein the laser join line or the multitude of bond points extends into the first substrate and into the metal foil and joins them together by direct melting,
wherein the metal foil is flexible in order to enable adaptation of the metal foil to the contact face of the first substrate.

2. The hermetically bonded assembly of claim 1,
wherein the metal foil is arranged along an outer edge region of the first substrate, and/or
wherein the metal foil covers the contact face of the first substrate in portions or regions, and/or
wherein the metal foil forms one or more contact points on the contact face of the first substrate.

3. The hermetically bonded assembly of claim 1,
wherein the metal foil in the join region comprising the laser join line(s), after introduction of the laser join line(s) by the joining process, no longer has any flexibility because of the adhesion to the first substrate, and/or
wherein the metal foil remains flexible outside the join region comprising the laser join line(s) after introduction of the laser join line(s).

4. The hermetically bonded assembly of claim 1,
wherein there is a mixing zone in the laser join line or the multitude of bond points in which material of the metal foil and material of the first substrate are mixed, and/or
wherein, in the mixing zone metal, material of the metal foil has entered the first substrate, and/or
wherein, in the mixing zone, material of the first substrate has entered the metal foil.

5. The hermetically bonded assembly of claim 1,
wherein the mixing zone has a height measured in a direction at right angles to the contact plane,
wherein the mixing zone has a height of at least 1 μm, and/or
wherein the mixing zone projects into the first substrate by 1 μm or more.

6. The hermetically bonded assembly of claim 1,
wherein the metal foil has a thickness of 500 μm or less, and/or
wherein the metal foil has a thickness of 10 μm or more.

7. The hermetically bonded assembly of claim 1,
wherein the metal foil adapts to unevenness in the contact face of the first substrate in that the metal foil is shaped permanently onto the first substrate by pressure.

8. The hermetically bonded assembly of claim 1,
wherein the metal foil has a weld rib on an underside on the opposite side from the contact face.

9. The hermetically bonded assembly of claim 1,
further comprising a metal component, wherein the metal component is inextricably bonded, to the metal foil, and/or
further comprising a plastic component, wherein the plastic component is inextricably bonded to the metal foil, and/or
further comprising a crystal component (106), where the crystal component (106) is inextricably bonded to the metal foil.

10. The hermetically bonded assembly of claim 9,
wherein the metal component the crystal component (106) or the plastic component is cohesively bonded to the metal foil by application of heat and/or pressure, with or without welding fillers, or by metal fusion welding, or by arc welding.

11. The hermetically bonded assembly of claim 9,
wherein the metal foil has a vertical section
and a molten bond in the laser join line has been introduced in the horizontal plane and, in sections, in a vertical region or
the metal component provides a frame or envelope of the hermetic assembly in that a lateral join by means of a conventional joining method has also been moved into the lateral edge region.

12. The hermetically bonded assembly of claim 1,
wherein the contact face of the first substrate has a touch contact region in which the first substrate is in two-dimensional touch contact with the metal foil,
wherein the touch contact face has an average distance between the first substrate and metal foil of not more than 1 μm, and
wherein the touch contact face especially corresponds to the contact plane.

13. The hermetically bonded assembly of claim 1,
wherein the metal foil consists of metal material, and/or
wherein the metal foil comprises metal of the Periodic Table.

14. The hermetically bonded assembly of claim 1,
wherein the metal foil comprises molybdenum, tungsten, silicon, aluminum, platinum, silver and gold, and/or
wherein the metal foil comprises an alloy, and/or comprises carbon, copper, manganese, chromium, magnesium, cobalt, nickel, tin, zinc, niobium, palladium, rhenium, indium, tantalum, titanium and iridium.

15. The hermetically bonded assembly of claim 1,
wherein the first substrate is a transparent substrate,
wherein the first substrate is a fiber sheet or a fiber rod and/or
wherein the first substrate comprises the following materials:
glass, glass-ceramic, silicon, germanium, sapphire or a combination thereof, ceramic material,
a crystal, optionally selected from the group consisting of crystalline quartz, yttrium oxide (Y2O3), zirconium oxide (ZrO2), aluminum oxide (A12O3), yttrium-doped zirconium oxide, yttrium-doped aluminum oxide, lanthanum-doped yttrium oxide, aluminum-doped aluminum nitride and manganese-doped aluminum oxide,
quartz glass, borosilicate glass, aluminosilicate glass, a glass-ceramic, optionally selected from the group consisting of Zerodur, Ceran or Robax, an optoceramic optionally selected from the group consisting of aluminum oxide, spinel, pyrochlore or aluminum oxynitride, calcium fluoride crystal or chalcogenide glass.

16. A hermetically sealed housing, comprising a hermetically bonded assembly of claim 1, comprising
a first substrate which is transparent in regions and/or to some degree to at least one wavelength range,
a metal foil,
wherein the metal foil is arranged with a contact face adjacent to a contact face of the first substrate,
wherein the metal foil is made flexible to compensate for unevenness in the contact face of the first substrate,
a function region,
a laser join line or a multitude of bond points for direct and immediate joining of the metal foil to the first substrate, at or in the contact areas, for hermetic sealing of the function region,
wherein the laser join line or the multitude of bond points extends into the first substrate and into the metal foil and joins them together by direct melting.

17. The hermetically sealed housing of claim 16, wherein the function region is an optical coating of the first substrate, a layer comprising one or more light-emitting diodes (LED), a polarizer or a hermetically sealed accommodating cavity for accommodating an accommodation object.

18. A method of producing a hermetically sealed bonded assembly, comprising the steps of:
providing a first substrate and a metal foil,
pressing the metal foil onto the first substrate such that, at a contact plane which is formed between the metal foil and the first substrate, the metal foil is in touch contact at least in portions or regions with the first substrate,
wherein the metal foil adapts to unevenness in the contact face of the first substrate via the pressing,
wherein the first substrate comprises a transparent material, and
hermetically tight bonding of the metal foil and the first substrate to one another by direct joining to one another in the region of the contact face, such that a mixing zone is formed, which projects into the first substrate and into the metal foil and joins these directly to one another by fusion.

19. The method of claim 18, further comprising the step of
after the hermetically tight bonding, placing a metal component onto the bond, and
joining the metal component to the bond by application of heat and/or pressure, with or without welding fillers.

20. The method of claim 18, wherein the metal foil has a vertical section and a molten bond in the laser join line has been introduced in the horizontal plane and, in sections, in a vertical region or the metal component provides a frame or envelope of the hermetic assembly in that a lateral join by means of a conventional joining method is also moved into the lateral edge region.

21. The method of claim 18, further comprising the step of
checking the hermetic bond by ascertaining a distance profile between the at least two joining partners, and/or
ascertaining a first bond quality index Q1 to check the mechanical strength and/or hermeticity of the bond.

22. A housing or hermetically bonded assembly produced by the method of claim 18.
